(19) United States
(12) Patent Application Publication
(10) Pub. No.: US 2021/0153376 A1
(43) Pub. Date: May 20, 2021

(54) RACK MOUNT SYSTEMS

(71) Applicant: ARRIS Enterprises LLC, Suwanee, GA (US)

(72) Inventors: Sergio Antonio Delon Canseco, Guadalupe (MX); Oswaldo Enrique Linares Rivas, Guadalupe (MX); Carlos Paul Gonzalez Inda, Guadalupe (MX); Julio Cesar Ayala Vera, Apodaca (MX); Luis Carlos Lopez Moreno, Apodaca (MX)

(73) Assignee: ARRIS Enterprises LLC, Suwanee, GA (US)

(21) Appl. No.: 16/953,764

(22) Filed: Nov. 20, 2020

Related U.S. Application Data
(60) Provisional application No. 62/937,927, filed on Nov. 20, 2019.
(60) Provisional application No. 62/966,415, filed on Jan. 27, 2020.

(51) Int. Cl. H05K 7/18; F16F 1/373; F16F 15/08

(52) U.S. Cl. CPC H05K 7/18; F16F 1/3732; F16F 15/08; F16F 2232/08; F16F 2234/00; F16F 2230/0005; F16F 2234/02; F16F 2224/025

(57) ABSTRACT

Rack mount systems and vibration absorbing devices, vibration absorber systems, and adjustable bracket assemblies for those rack mount systems are disclosed. In one embodiment, a vibration absorber includes a compressible shaft extending from a first end to a second end. The compressible shaft defines a cylindrical central bore along a major axis of the compressible shaft. A first compressible annular flange extends distally away from the first end, while a second compressible annular flange extends distally away from the second end. A hub between the first compressible annular flange and the second compressible annular flange includes a plurality of vibration-dampening arms extending distally therefrom. The vibration absorber can be over-molded to a mounting bracket.

### CROSS-REFERENCE TO RELATED APPLICATIONS

This application claims the benefit of U.S. Provisional Patent Application Ser. No. 62/937,927 filed Nov. 20, 2019 and entitled “Damping Bracket System;” and U.S. Provisional Patent Application Ser. No. 62/966,415 filed Jan. 27, 2020 and entitled “Adjustable Bracket Assemblies.” The complete disclosures of the above applications are hereby incorporated by reference for all purposes.

### BACKGROUND

This disclosure relates generally to rack mount systems, and more particularly to vibration absorbing devices, vibration absorber systems, and adjustable bracket assemblies for the rack mount systems.

Computer hardware devices are often placed into mechanical mounting structures known as “rack mounting systems” or “rack mount systems.” Computer hardware components, network servers, communication routers, networking switches, digital satellite receivers, computer system devices, and other components are placed into a chassis that is arranged, generally in a vertical stack, with other chassis in a central cabinet known as a “rack.” A sliding rail structure or bracket assembly is coupled to each chassis secures the same within the rack and allows each chassis to be selectively withdrawn along the sliding structure from the rack for service or other operations. These sliding rail structures generally allow each chassis to be fully withdrawn from the rack on an individual basis so that the components within the chassis can be accessed without decoupling the chassis from the sliding rail structure or the sliding rail structure from the rack.

One problem with these rack mount systems involves vibration. If a vibrating force interacts with the rack, any of the sliding rail structures, or any of the chassis, this vibrating force can translate to other hardware components, thereby potentially causing the components to malfunction or electrical connections to, or within, a chassis to open.

Another problem with the rack mount systems is that the rack-mountable components housed in the rack mount systems do not have a standardized depth. As a result, attaching rack-mountable components generally require the use of tools and/or fasteners, and/or the use of particular mounting brackets and shelves designed for components of a particular depth. Additionally, the attachment process can take a lot of effort and time. It would be advantageous to have an improved devices and systems that worked to reduce or eliminate vibrational forces from translating through rack mounted hardware configurations and/or provide adjustable bracket assemblies that can be used to attach components of various depths to a rack mount system to reduce the effort and time in attaching those components.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present disclosure.

FIG. 1 illustrates a perspective view of one explanatory vibration absorber in accordance with one or more embodiments of the disclosure.

FIG. 2 illustrates a front elevation view of one explanatory vibration absorber in accordance with one or more embodiments of the disclosure.

FIG. 3 illustrates a rear elevation view of one explanatory vibration absorber in accordance with one or more embodiments of the disclosure.

FIG. 4 illustrates a right side elevation view of one explanatory vibration absorber in accordance with one or more embodiments of the disclosure.

FIG. 5 illustrates another front elevation view of one explanatory vibration absorber in accordance with one or more embodiments of the disclosure showing hidden elements in dashed line.

FIG. 6 illustrates a partial view of one explanatory vibration absorber system in accordance with one or more embodiments of the disclosure.

FIG. 7 illustrates a first perspective view of one explanatory vibration absorber system in accordance with one or more embodiments of the disclosure.

FIG. 8 illustrates another perspective view of explanatory vibration absorber system in accordance with one or more embodiments of the disclosure.

FIG. 9 illustrates a perspective view of one explanatory chassis in accordance with one or more embodiments of the disclosure.

FIG. 10 illustrates a partial sectional view of another explanatory vibration absorber system in accordance with one or more embodiments of the disclosure.

FIG. 11 illustrates simulated performance of one explanatory vibration absorber system in accordance with one or more embodiments of the disclosure.

FIG. 12 illustrates a front elevation view of another explanatory vibration absorber in accordance with one or more embodiments of the disclosure showing hidden elements in dashed line.

FIG. 13 illustrates a front elevation view of yet another explanatory vibration absorber in accordance with one or more embodiments of the disclosure showing hidden elements in dashed line.

FIG. 14 illustrates a front elevation view of still another explanatory vibration absorber in accordance with one or more embodiments of the disclosure showing hidden elements in dashed line.

FIG. 15 illustrates various embodiments of the rack systems of the disclosure.

FIG. 16 is a perspective view of one bracket assembly having a front bracket, side supports, and a rear bracket movably connected to the side supports and front bracket in accordance with one or more embodiments of the disclosure.

FIG. 17 is an exploded view of latching mechanisms attached to the front bracket of the bracket assembly of FIG. 16 in accordance with one or more embodiments of the disclosure.

FIG. 18 is a partial view of the bracket assembly of FIG. 16 showing a right end portion of the rear bracket movably connected to a side support in accordance with one or more embodiments of the disclosure.

FIG. 19 is a perspective view of an upper roller of the rear bracket showing one biasing mechanism, shown with front and rear covers of the upper roller removed in accordance with one or more embodiments of the disclosure.

FIG. 20 is a partial view of the bracket assembly of FIG. 16 showing another biasing mechanism in accordance with one or more embodiments of the disclosure.

FIG. 21 is a perspective view of the bracket assembly of FIG. 16 shown supporting one electronic component in accordance with one or more embodiments of the disclosure.

FIGS. 22-23 are partial views of the bracket assembly of FIG. 21, showing first and second tabs of the latching mechanism of FIG. 17 contacting the supported electronic component to secure the electronic component to the bracket assembly in accordance with one or more embodiments of the disclosure.

FIG. 24 illustrates a prior art rack mount system.

FIG. 25 illustrates a prior art chassis and sliding rail system.

FIG. 26 illustrates a partial sectional view of a prior art chassis and sliding rail system.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present disclosure.

### DETAILED DESCRIPTION

Embodiments of the disclosure are now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions.

The terms “substantially”, “essentially”, “approximately”, “about” or any other version thereof, are defined as being close to as understood by one of ordinary skill in the art, and in one non-limiting embodiment the term is defined to be within 10 percent, in another embodiment within 5 percent, in another embodiment within 1 percent and in another embodiment within 0.5 percent. The term “coupled” as used herein is defined as connected, although not necessarily directly. Also, reference designators shown herein in parenthesis indicate components shown in a figure other than the one in discussion. For example, talking about a device (10) while discussing figure A would refer to an element, 10, shown in figure other than figure A.

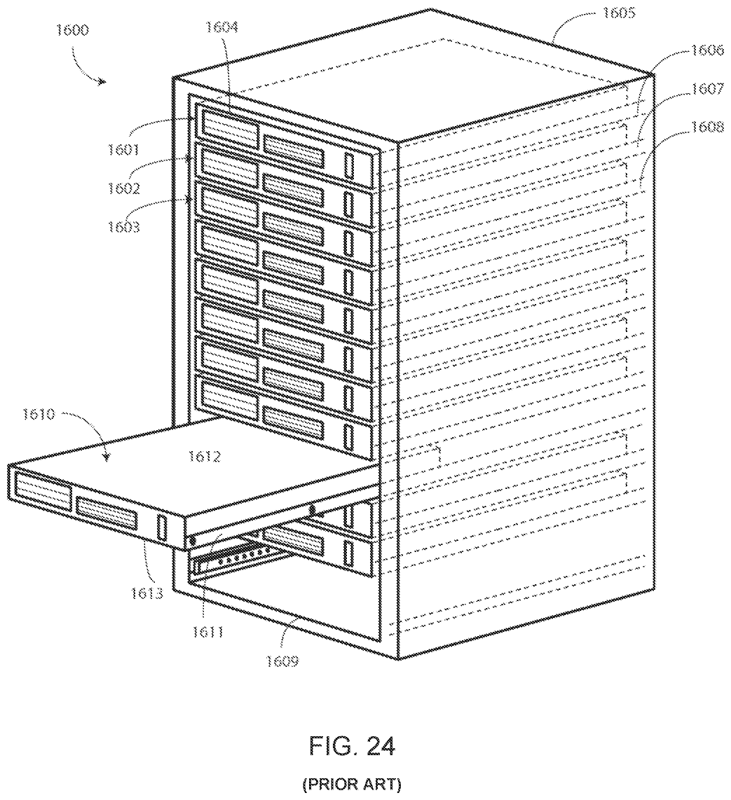

Turning first to FIG. 24, illustrated therein is an example of a prior art rack mount system 1600. The prior art rack mount system 1600 includes a plurality of rack-mountable components or rack mount hardware devices 1601, 1602, 1603. Each of the rack mounted hardware devices 1601, 1602, 1603 is housed in a chassis 1604. Examples of rack mounted hardware devices 1601, 1602, 1603 include network computer servers, network routers, network switches, and digital satellite receivers. These are illustrative only, as other examples of device suitable for rack mount configurations are included in this disclosure.

As shown in FIG. 24, the rack mounted hardware devices 1601, 1602, 1603 are situated in a vertical mounting rack 1605, which is shown illustratively as being configured as a cabinet. The vertical mounting rack 1605 includes a plurality of bracket assemblies or sliding rail structures 1606, 1607, 1608 coupled to each chassis 1604 of each rack mounted hardware device 1601, 1602, 1603.

These sliding rail structures 1606, 1607, 1608 allow each rack mounted hardware device 1601, 1602, 1603 to translate laterally by sliding along the sliding rail structures 1606, 1607, 1608 such that they can be withdrawn or inserted into the vertical mounting rack 1605 without having to decouple the chassis 1604 of any rack mounted hardware device 1601, 1602, 1603 from either the vertical mounting rack 1605 or its corresponding sliding rail structure 1606, 1607, 1608. As shown in FIG. 24, rack mounted hardware device 1610 has been withdrawn from the vertical mounting rack 1605 by sliding along its corresponding sliding rail structure 1611. Thereafter, the racked mounted hardware device 1610 and its sliding rail structure 1611 can be removed from the vertical mounting rack 1605 so that the upper cover 1612 of the rack mounted hardware device 1610 can be removed. The internal components supported by the chassis 1613 can be serviced.

The vertical mounting rack 1605 includes a front opening 1609 through which the rack mounted hardware devices 1601, 1602, 1603 can be withdrawn. The vertical mounting rack 1605 can also include a rear opening for making electrical connections to each of the rack mounted hardware devices 1601, 1602, 1603 as well. Doors, which are not shown, can be included to close either the front opening 1609 or the rear opening to protect the rack mounted hardware devices 1601, 1602, 1603 from foreign objects. Where included, these doors can be vented to allow airflow into the vertical mounting rack 1605 to cool the rack mounted hardware devices 1601, 1602, 1603.

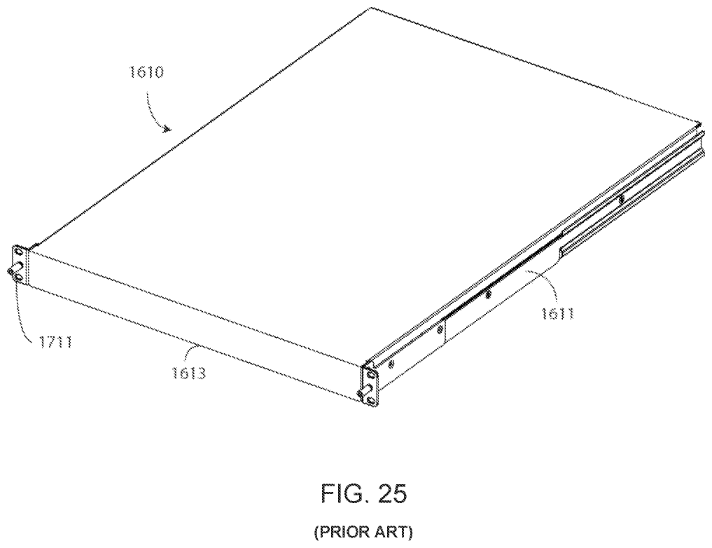

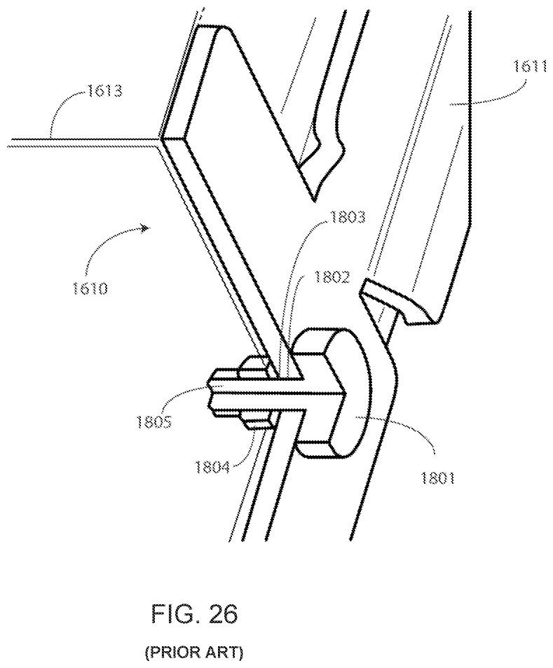

Turning to FIG. 25, illustrated therein is one example of a rack mounted hardware device 1610 when decoupled from the vertical mounting rack (1605) of FIG. 24. As shown in FIG. 25, a left sliding rail structure 1611 and a right sliding rail structure 1711, each of which are mechanically coupled to the chassis 1613 of the rack mounted hardware device 1610. The left sliding rail structure 1611 and a right sliding rail structure 1711 are configured as metal brackets that are attached to the chassis 1613 of the rack mounted hardware device 1610. In one or more embodiments, the left sliding rail structure 1611 and a right sliding rail structure 1711 are bolted to the chassis 1613 of the rack mounted hardware device 1610. One example of how this can occur is shown in FIG. 26.

Turning now to FIG. 26, illustrated therein is a partial sectional view of the rack mounted hardware device 1610 of FIG. 24. FIG. 26 illustrates the chassis 1613 and the left sliding rail structure 1611 in a cut-away partial view. As shown in FIG. 26, a screw 1801 is passed from an exterior of the chassis 1613 through an aperture 1802 in the left sliding rail structure 1611. The shaft 1805 of the screw 1801 then passes through an aperture 1803 in the chassis 1613. A swage nut 1804, which is sometimes referred to as a self-clinching nut, is then coupled to the shaft 1805 of the screw 1801 to fixedly couple the left sliding rail structure 1611 to the chassis 1613. Multiple swage nuts 1804 can be used to couple the left sliding rail structure 1611 to the chassis 1613. The right sliding rail structure 1711 can be coupled to the chassis 1613 in a similar manner.

The problem with this prior art connection system is that the components situated within the chassis 1613 will experience vibration whenever the left sliding rail structure 1611 or right sliding rail structure 1711 experiences vibration due to the fact that there is a fixed connection by way of the screw 1801 and swage nut 1804 between the chassis 1613 and the left sliding rail structure 1611 and right sliding rail structure 1711. The interaction between the left sliding rail structure 1611 and/or right left sliding rail structure 1711, the screw 1801, the swage nut 1804, and the chassis 1613 cause a high vibration transmissibility to the components situated within the chassis 1613. Received vibrational forces therefore translate through the left sliding rail structure 1611 or right left sliding rail structure 1711, through the screw 1801, and to the chassis 1613 due to the fact that these are fixedly coupled, rigid components that are generally manufactured from metals such as aluminum and steel.

Moreover, if any of the rack mounted hardware devices (1601, 1602, 1603) of the prior art rack mount system (1600), or the vertical mounting rack (1605), or their corresponding sliding rail structures (1606, 1607, 1608) receive vibrational or impact forces, the rigid coupling between metal components shown in FIG. 26 causes the vibration to translate to other rack mounted hardware devices, e.g., rack mounted hardware device 1601, potentially causing components situated within the chassis 1613 to malfunction. In severe cases, excessive vibration can even cause general failure of the prior art rack mount system (1600). Thus, a technician simply “slamming” a rack mounted hardware device back into a rack can potentially damage the expensive components operating within other chassis of the rack.

Advantageously, embodiments of the disclosure provide a solution to these maladies by providing a vibration absorber that situates between a fastener and a chassis and sliding rail structure. In one or more embodiments, the vibration absorber comprises a compressible shaft extending from a first end to a second end. In one or more embodiments, the compressible shaft defines a central bore that extends from the first end to a second end along a major axis of the compressible shaft. In one or more embodiments, the central bore is cylindrical.

In one or more embodiments, a first compressible annular flange extends distally away from the first end of the compressible shaft. A second compressible annular flange then extends distally away from the second end of the compressible shaft. In one or more embodiments, each of the first compressible annular flange and the second compressible annular flange is configured as a disc and includes a centrally located aperture that is concentrically aligned with the major axis.

In one or more embodiments, the compressible shaft defines a hub between the first compressible annular flange and the second compressible annular flange. In one or more embodiments, the hub comprises a plurality of vibration-dampening arms extending distally from the hub and radially outward from the central axis of the compressible shaft.

The vibration-dampening arms can be configured in a variety of ways. In one embodiment, the vibration-dampening arms are configured as arched lobes. For example, the arched lobes can have an exterior surface defined by semi-elliptical contour, an at least partially parabolic contour, a semi-circular contour, or another contour. In other embodiments, a terminal end of each vibration-dampening arm defines a partially rectangular cross section, a partially triangular cross section, a polygonal cross section, or another cross section.

In still other embodiments, each vibration-dampening arm extends distally from the hub to a header. In one or more embodiments, the header is wider than each vibration-dampening arm. In one or more embodiments, the header includes a convex exterior surface that can be biased against the interior surface of an aperture of a sliding rail assembly. Other configurations of vibration-dampening arms will be described below. Still others will be obvious to those of ordinary skill in the art having the benefit of this disclosure.

In one or more embodiments, the vibration absorber is situated within the aperture of a mounting bracket configured as a sliding rail assembly component. Illustrating by example, in one embodiment the vibration absorber is over-molded into the aperture of a mounting bracket such that it is perdurably coupled to the mounting bracket. In one or more embodiments, this results in the first compressible annular flange being situated against a first major face of the mounting bracket, while the second compressible annular flange is situated against a second major face of the mounting bracket.

In one or more embodiments, the shaft defines a hub that situates within the aperture of the mounting bracket. As noted above, in one or more embodiments the hub comprises a plurality of vibration-dampening arms situated between the hub and the interior surface of the aperture. A fastener, such as a screw, can then be situated within the cylindrical bore. In one or more embodiments, such as where the interior surface of the aperture of the mounting bracket is round, this action can cause each vibration-dampening arm to be compressed into a deformed shape due to the fact that the vibration absorber is manufactured from a compressible material. In one or more embodiments the compressible material is an elastomeric material. Other compressible materials, including rubber, silicone, and compressible thermoplastics suitable for manufacturing the vibration absorber will be obvious to those of ordinary skill in the art having the benefit of this disclosure.

In other embodiments, the interior surface of the aperture of the mounting bracket has a contour that is complementary in shape to the vibration-dampening arms. Illustrating by example, if the hub of the vibration absorber includes vibration-dampening arms that are configured as convex arched lobes, the interior surface of aperture of the mounting bracket can define one or more concave arched recesses into which the vibration-dampening arms situate. Where there is space between vibration-dampening arms, the interior surface of the mounting bracket can be complementary in shape to the contour of the hub along these spaces.

In one or more embodiments, when the mounting bracket is coupled to a chassis to create a vibration absorber system, in addition to the vibration-dampening arms being compressed between the fastener and the mounting bracket, the first compressible annular flange is compressed between the mounting bracket and the chassis. The second compressible annular flange is then compressed between a head of the fastener and the mounting bracket when a coupler, such as a swage nut, is coupled to the fastener, thereby causing the fastener to bias the chassis and mounting bracket together.

Where manufactured from an elastomeric material, in one or more embodiments the viscoelasticity, weak intermolecular forces, and low Young's modulus of the material of the material reduce the ability of either the fastener or the mounting bracket to translate vibrational and impact forces from to the chassis, thereby reducing the amount of vibration experienced by the components situated within the chassis. Simulations show that the dampening effect of using a vibration absorber configured in accordance with one or more embodiments of the disclosure can be reduced over twenty-five percent, which provides an awesome protective benefit to the components situated within the chassis, thereby prolonging their mean time between failure and extending their operational performance.

In one or more embodiments, the vibration absorber is placed as a link between the mounting bracket and the chassis. In one or more embodiments, the geometry of the vibration absorber, combined with its material properties, damps the amplitude of any vibrational forces transmitted from the rack within which the vibration absorber system is situated. This offers numerous benefits discussed below. First, vibration absorber systems configured in accordance with embodiments of the disclosure reduce vibration transmissibility conditions within rack mount systems. Second, vibration absorber systems configured in accordance with embodiments of the disclosure reduce the risk of failure of internal components that occur as a result of vibration.

Third, vibration absorber systems configured in accordance with embodiments of the disclosure help to increase the lifespan of components of rack mount systems. Fourth, vibration absorber systems configured in accordance with embodiments of the disclosure help to extend the duration between which service of the components is required. This reduces costs associated with such services. Fifth, vibration absorber systems configured in accordance with embodiments of the disclosure can be applied to any number of rack mount systems.

In one or more embodiments, the interaction between the mounting bracket and the vibration absorber is defined by a specific vibration absorber design that prevents the hub of the vibration absorber from rotating within the aperture of the mounting bracket when a fastener, e.g., a screw, is rotated within the central bore of the vibration absorber to attach the mounting bracket to a chassis. This specific vibration absorber design further helps to ensure that the vibration absorber remains securely coupled to the mounting bracket in one or more embodiments.

In one or more embodiments, an adjustable bracket assembly includes a front support, side supports, and a rear support. A roller assembly may be attached to the rear support. In one or more embodiments, the roller assembly defines a channel to slidably engaged a respective side support. A biasing mechanism may be attached to the rear support and the biasing mechanism urges the rear support toward the front support. In one or more embodiments, the biasing mechanism includes a spring. The spring may be contained within at least one roller of the roller assembly or may be external the at least one roller.

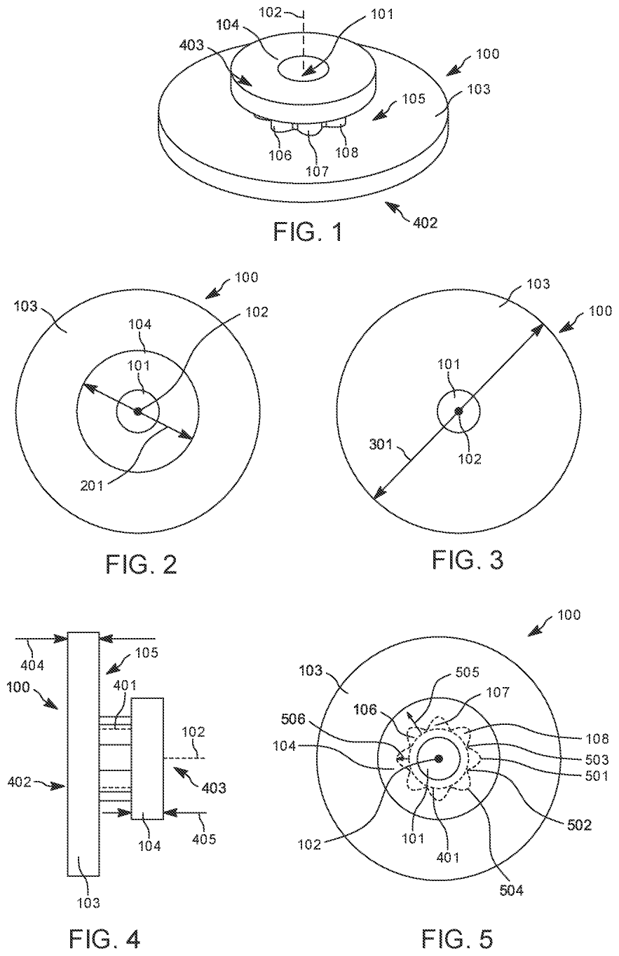

Turning now to FIGS. 1-5, illustrated therein is one explanatory vibration absorber 100 configured in accordance with one or more embodiments of the disclosure. FIG. 1 illustrates a perspective view of the vibration absorber 100, while FIG. 2 illustrates a front elevation view of the vibration absorber 100. FIG. 3 illustrates a rear elevation view of the vibration absorber 100, while FIG. 4 illustrates a right side elevation view of the vibration absorber 100. FIG. 5 illustrates another front elevation view of the vibration absorber showing hidden elements in dashed line.

In one or more embodiments, the vibration absorber 100 comprises a compressible shaft 401. In one or more embodiments, the compressible shaft 401 extends from a first end 402 to a second end 403. In one or more embodiments, the compressible shaft 401 defines a central bore 101 extending from the first end 402 to the second end 403 along a major axis 102 of the compressible shaft 401.

In the illustrative embodiment of FIGS. 1-5, the central bore 101 is cylindrical. However, in other embodiments the inner surface of the central bore 101 can take other shapes. For example, the inner surface of the central bore 101 can have a triangular cross section in another embodiment. In yet another embodiment, the inner surface of the central bore 101 has a rectangular cross section. In still another embodiment, the inner surface of the central bore 101 has a hexagonal cross section. Other contours for the inner surface of the central bore 101 will be obvious to those of ordinary skill in the art having the benefit of this disclosure.

In one or more embodiments, a first compressible annular flange 103 extends distally away from the first end 402 of the compressible shaft 401, while a second compressible annular flange 104 extends distally from the second end 403 of the compressible shaft 401. In this illustrative embodiment, each of the first compressible annular flange 103 and the second compressible annular flange 104 are configured as a disc having a circular cross section, with each of the first compressible annular flange 103 and the second compressible annular flange 104 having a corresponding centrally located aperture that is concentrically aligned with the major axis 102 of the compressible shaft 401.

In one or more embodiments, the compressible shaft 401 defines a hub 105 between the first compressible annular flange 103 and the second compressible annular flange 104. In one or more embodiments, the hub 105 comprises a plurality of vibration-dampening arms 106, 107, 108 extending distally from the hub 105. As shown in FIGS. 1, 4, and 5, in one or more embodiments the vibration-dampening arms 106, 107, 108 extend radially outward from the major axis 102 of the compressible shaft 401.

In this illustrative embodiment, the vibration-dampening arms 106, 107, 108 are each configured as an arched lobe, as shown in FIG. 5. Each vibration-dampening arm 106, 107, 108 extends from the hub 105 to an apex 501 that separates two nadirs 502, 503. In the illustrative embodiment of FIGS. 1-5, the exterior surface 504 of each vibration-dampening arm 106, 107, 108 is at least partially parabolic, as the cross section of the exterior surface 504 is convex parabolic between nadirs. Thus, the cross section of the exterior surface 504 in this illustrative embodiment is that of a parabola.

In other embodiments, the vibration-dampening arm 106, 107, 108 can be configured to have exterior surfaces that take different shapes. For example, in another embodiment the exterior surface 504 of the vibration-dampening arms 106, 107, 108 is defined by a semi-elliptical contour. In yet another embodiment, the exterior surface 504 of the vibration-dampening arms 106, 107, 108 is defined by a semi-circular contour. Other exterior surface cross-sectional shapes for the vibration-dampening arms 106, 107, 108 will be described below with reference to FIGS. 12-14. Still others will be obvious to those of ordinary skill in the art having the benefit of this disclosure.

In the illustrative embodiment of FIGS. 1-5, the vibration absorber 100 has eight vibration-dampening arms 106, 107, 108. However, in other embodiments, the vibration absorber 100 comprises fewer than eight vibration-dampening arms 106, 107, 108. In still other embodiments, the vibration absorber 100 has more than eight vibration-dampening arms 106, 107, 108, and so forth.

In the illustrative embodiment of FIGS. 1-5, the first compressible annular flange 103 has a greater diameter than does the second compressible annular flange 104. Said differently, in one or more embodiments the diameter 301 of the first compressible annular flange 103 is greater than the diameter 201 of the second compressible annular flange 104. In other embodiments, the diameter 301 of the first compressible annular flange 103 can be equivalent to the diameter 201 of the second compressible annular flange 104. In still other embodiments, the diameter 301 of the first compressible annular flange 103 can be less than the diameter 201 of the second compressible annular flange 104.

In one or more embodiments, the width 404 of the first compressible annular flange 103 is substantially equivalent to the width 405 of the second compressible annular flange 104. In other embodiments, the width 404 of the first compressible annular flange 103 will be greater than the width 405 of the second compressible annular flange 104. In still other embodiments, the width 404 of the first compressible annular flange 103 will be less than the width 405 of the second compressible annular flange 104.

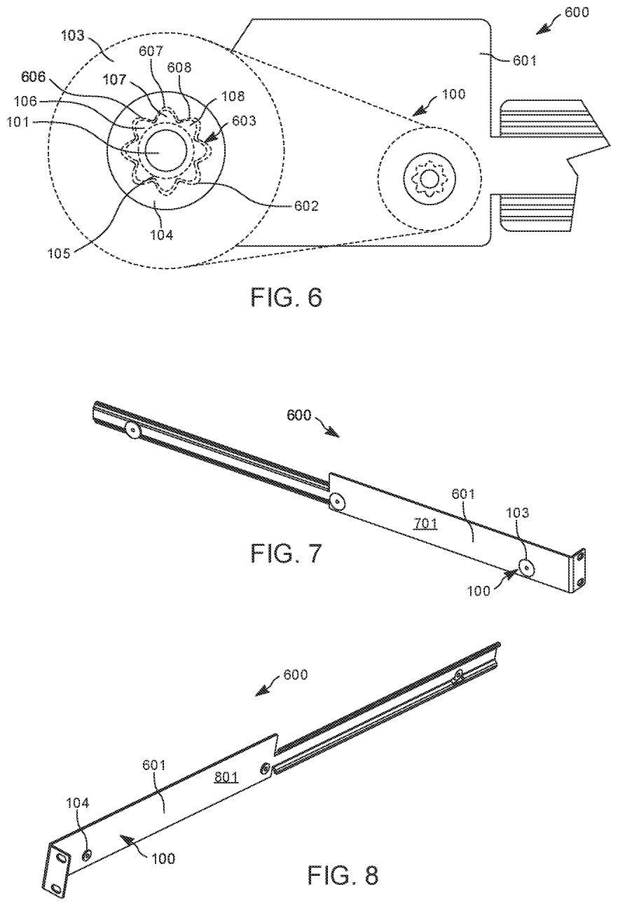

As best shown in FIG. 5, in this illustrative embodiment the second compressible annular flange 104 extends 505 farther from the compressible shaft 401 than do the vibration-dampening arms 106, 107, 108. Said differently, in this embodiment the second compressible annular flange 104 extends 505 farther from the compressible shaft 401 than the tallest vibration-dampening arm extends 506 from the compressible shaft 401. As will be shown in more detail below with reference to FIG. 6, this helps to keep the vibration absorber 100 securely coupled within an aperture of a mounting bracket.

In one or more embodiments, the vibration absorber 100 is manufactured from a compressible material. In one or more embodiments the vibration absorber 100 is manufactured from an elastomeric material. In other embodiments, the vibration absorber 100 is manufactured from one or more of rubber, silicone, and/or compressible thermoplastics. Still other materials suitable for manufacturing the vibration absorber 100 will be obvious to those of ordinary skill in the art having the benefit of this disclosure.

In one or more embodiments, the vibration absorber 100 is manufactured as a singular, unitary component. Said differently, in one or more embodiments the compressible shaft 401, the first compressible annular flange 103, the second compressible annular flange 104, and the plurality of vibration-dampening arms 106, 107, 108 are manufactured as a single, unitary component where these items are not separable from each other. As will be shown below, in one or more embodiments the compressible shaft 401, the first compressible annular flange 103, the second compressible annular flange 104, and the plurality of vibration-dampening arms 106, 107, 108 are manufactured as a single, unitary component by way of an over-molding process situating the vibration absorber 100 within an aperture of a mounting bracket.

In other embodiments, the compressible shaft 401, the first compressible annular flange 103, the second compressible annular flange 104 can be manufactured from separate components so that they can be attached to a mounting bracket without requiring over-molding. Illustrating by example, in another embodiment the first compressible annular flange 103 and the compressible shaft 401 are manufactured as a unitary component by way of an injection molding process, with the second end 403 comprising a threaded connection. The compressible shaft 401 can be passed through an aperture of a mounting bracket, after which the second compressible annular flange 104, which can include a complementarily threaded central aperture, can be coupled to the second end 403 of the compressible shaft 401 to couple the vibration absorber 100 to the mounting bracket. Other techniques for manufacturing the vibration absorber 100 will be obvious to those of ordinary skill in the art having the benefit of this disclosure.

Turning now to FIGS. 6-8, illustrated therein is one explanatory vibration absorber system 600 configured in accordance with one or more embodiments of the disclosure. FIG. 6 illustrates a partial view of the vibration absorber system 600, while FIG. 7 illustrates a first perspective view of the vibration absorber system 600. FIG. 8 illustrates a second perspective view of the vibration absorber system 600.

As shown in FIGS. 6-8, a bracket assembly or mounting bracket 601 is configured as a sliding rail structure arm that is suitable for coupling to a chassis so that the chassis can slide into, and out of, a rack mount system. The mounting bracket 601 defines at least one aperture 602 having an interior surface 603. In this illustrative embodiment, as best seen in FIGS. 7-8, the mounting bracket 601 defines three such apertures.

In this illustrative embodiment, the vibration absorber 100 is situated within the at least one aperture 602. In this embodiment, the vibration absorber 100 has been over-molded into the aperture 602 of the mounting bracket 601. As the first compressible annular flange 103 and the second compressible annular flange 104 have diameters (301, 201) that are greater than that of the aperture 602, this results in the vibration absorber 100 being perdurably coupled to the mounting bracket 601.

As shown in FIGS. 6-8, in one or more embodiment the first compressible annular flange 103 is situated, and optionally biased, against a first major face 701 of the mounting bracket 601. In this embodiment the second compressible annular flange 104 is situated, and optionally biased against, a second major face 801 of the mounting bracket 601. The first compressible annular flange 103 and the second compressible annular flange 104 can optionally be adhesively coupled or attached to the first major face 701 and second major face 801 of the mounting bracket 601, respectively, as well.

Illustrating by example, where the vibration absorber 100 is over-molded to the mounting bracket 601 as a unitary component, in one or more embodiments this results in the first compressible annular flange 103 being situated against, and attached to, against the first major face 701 of the mounting bracket 601. Similarly, this results in the second compressible annular flange 104 being situated against, and attached to, the second major face 801 of the mounting bracket 601.

By contrast, where the vibration absorber 100 is be manufactured from separate components so that they can be attached to the mounting bracket 601 without requiring over-molding, this can allow the first compressible annular flange 103 being situated against the first major face 701 while the second compressible annular flange 104 is situated against the second major face 801. If the first compressible annular flange 103 and the compressible shaft 401 are manufactured as a unitary component by way of an injection molding process, with the second end 403 comprising a threaded connection, the compressible shaft 401 can be passed through the aperture 602 of a mounting bracket 601. Thereafter, the second compressible annular flange 104 can be threaded to the second end 403 of the compressible shaft 401, thereby biasing the first compressible annular flange 103 against the first major face 701 and the second compressible annular flange 104 against the second major face 801, and so forth.

As best shown in FIG. 6, in this illustrative embodiment the hub 105 situates within the aperture 602 of the mounting bracket 601. The vibration-dampening arms 106, 107, 108 situate between the hub 105 and the interior surface 603 of the aperture 602.

The interior surface 603 of the aperture 602 of the mounting bracket 601 can take a variety of shapes. In one embodiment, the interior surface 603 of the aperture 602 of the mounting bracket 601 is shaped differently from the exterior surface defined by the hub 105 and plurality of vibration-dampening arms 106, 107, 108. For example, in one embodiment the interior surface 603 of the aperture 602 of the mounting bracket 601 is circular, while the arched lobes defining the vibration-dampening arms 106, 107, 108 define what may be called a “star-shaped” feature or “flower-shaped” feature. When a fastener, such as a screw, is passed through the central bore 101, in one or more embodiments this action can cause each vibration-dampening arm 106, 107, 108 to be compressed into a deformed shape due to the fact that the vibration absorber 100 is manufactured from a compressible material, such as an elastomer.

In the illustrative embodiment of FIGS. 6-8, however, the interior surface 603 of the aperture 602 is not shaped like a circle. Instead, in this embodiment the interior surface 603 of the aperture 602 of the mounting bracket 601 has a contour that is complementary in shape to the exterior surface defined by the hub 105 and/or plurality of vibration-dampening arms 106, 107, 108.

Because the vibration-dampening arms 106, 107, 108 of this embodiment are configured as arched lobes, and in particular, as convex arched lobes, the interior surface 603 of aperture 602 of the mounting bracket 601 define one or more concave arched recesses 606, 607, 608. In this illustrative embodiment, the vibration-dampening arms 106, 107, 108 situated into the concave arched recesses 606, 607, 608 on a one to one basis. Advantageously, the geometry and material properties of the vibration absorber 100, combined with the shape of the interior surface 603 of the aperture 602 of the mounting bracket 601, prevent the vibration absorber 100 from rotating along its major axis 102 when a fastener is passed through the central bore 101 and rotated.

In this illustrative embodiment, the hub 105 is surrounded by vibration-dampening arms 106, 107, 108. However, this is not always the case, as will be described below with reference to FIGS. 12-14. In embodiments such as those of FIGS. 12-14, i.e., where there is space between vibration-dampening arms, the interior surface 603 of the aperture 602 mounting bracket 601 can be complementary in shape to the contour of the hub along these interspaces between vibration-dampening arms.

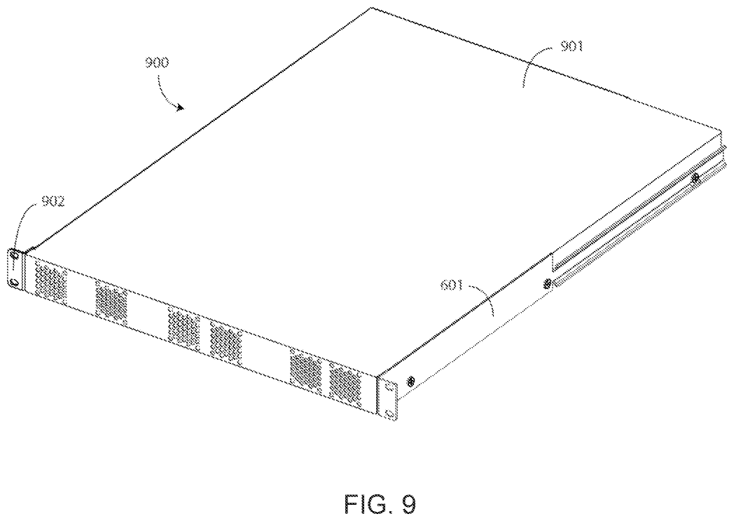

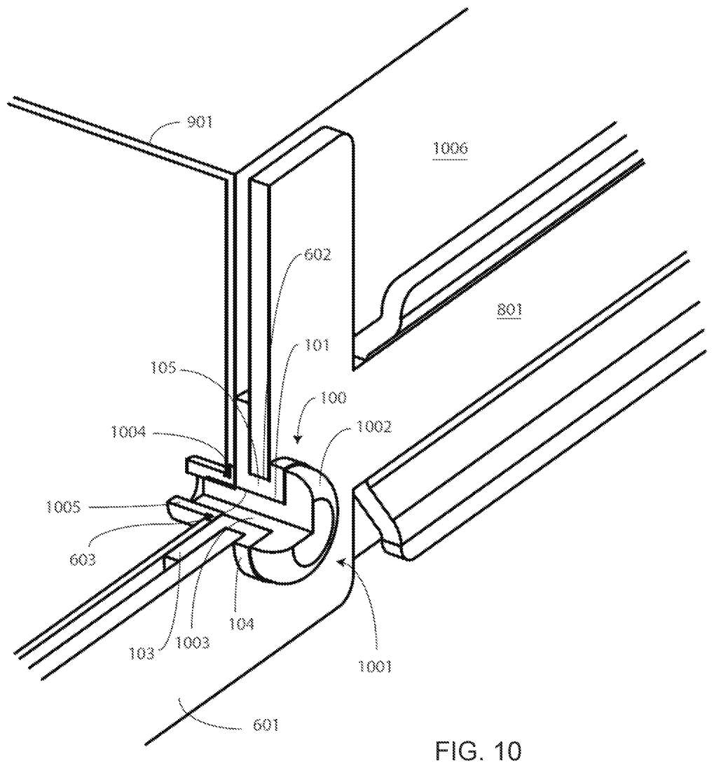

Turning now to FIG. 9, illustrated therein is another vibration absorber system 900 configured in accordance with one or more embodiments of the disclosure. As shown in FIG. 9, the mounting bracket 601 of FIGS. 6-8 has been coupled to the left side of a chassis 901. A mounting bracket 902 that is a mirror image of mounting bracket 601 has been coupled to the right side of the chassis 901. FIG. 10 illustrates a partial, sectional view of how this occurs in one or more embodiments.

Turning now to FIG. 10, as illustrated in this partial, sectional view, a fastener 1001, which is a screw in this embodiment, has been passed through the central bore 101 of the vibration absorber 100. The hub 105 of the vibration absorber 100 is situated within the aperture 602 of the mounting bracket 601. The fastener 1001 includes a head 1002 and a shaft 1003. The shaft 1003 passes through the central bore 101, while the inner surface of the head 1002 is situated against the second compressible annular flange 104 of the vibration absorber 100.

Once the shaft 1003 is passed through the central bore 101, it passes through an aperture 1004 in the chassis 901. A swage nut 1005 is then coupled to the shaft 1003 of the fastener 1001 to fixedly couple the mounting bracket 601 to the chassis 901. In this embodiment, the swage nut 1005 is situated inside the chassis 901.

In one or more embodiments, coupling the swage nut 1005 to the shaft 1003 of the fastener 1001 applies a biasing force compressing the first compressible annular flange 103 and the second compressible annular flange 104. In one or more embodiments, this biasing force causes the first compressible annular flange 103 to become compressed between an exterior surface 1006 of the chassis 901 and the first major face 701 of the mounting bracket 601. Additionally, as shown in FIG. 10, the second compressible annular flange 104 is compressed between the head 1002 and the second major face 801 of the mounting bracket 601. In one or more embodiments, it additionally causes the hub 105 and the vibration-dampening arms 106, 107, 108 to be compressed between the fastener 1001 and the interior surface 603 of the aperture 602 of the mounting bracket 601.

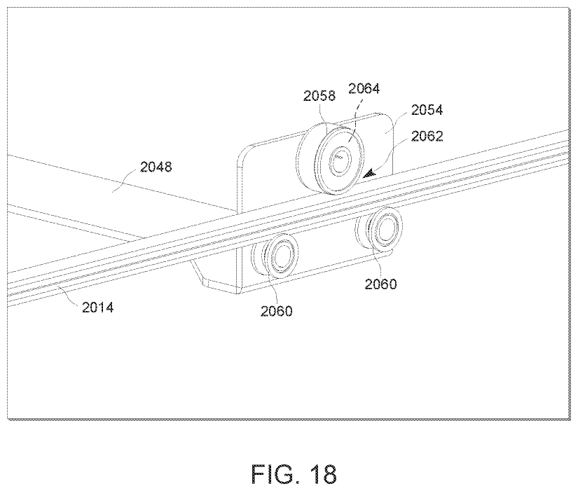

By situating the vibration absorber 100 between the fastener 1001 and the mounting bracket 601, vibration transmissibility is reduced. In one or more embodiments, this reduction in vibration transmissibility occurs due to the interaction between the mounting bracket 601 and the vibration absorber 100. In particular, the first compressible annular flange 103 of the vibration absorber 100 isolates the “metal on metal” contact between chassis 901 and the mounting bracket 601 that was problematic in the prior art design of FIG. 18. Moreover, the hub 105 of the vibration absorber 100 isolates the metal on metal interactions between the fastener 1001 and the mounting bracket 601. The second compressible annular flange 104 isolates the metal on metal contact between head 1002 of the fastener 1001 and the mounting bracket 601.

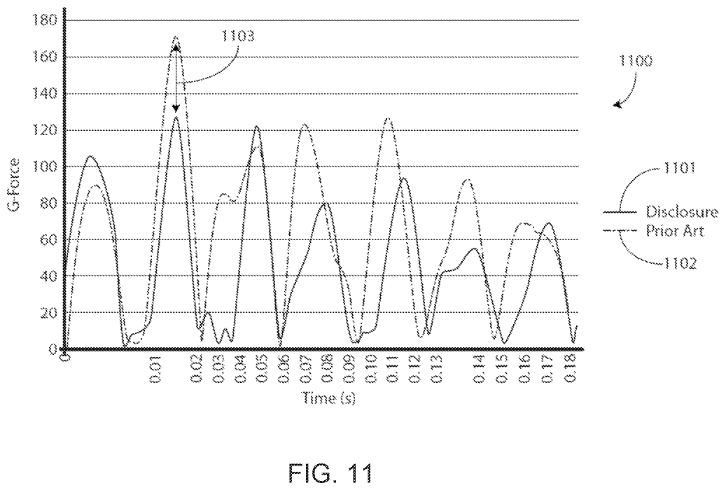

Turning now to FIG. 11, illustrated therein is a graph 1100 showing how dramatically embodiments of the present disclosure reduce vibration transmissibility compared to the prior art design of FIG. 18. The graph 1100 of FIG. 11 represents the results of a computer simulation comparing the design of FIG. 10 to the prior art design of FIG. 18. Plot 1101 represents the design of FIG. 10, while plot 1102 represents the prior art design of FIG. 18.

In the computer simulation, the simulated chassis was fixed to mounting brackets, with the mounting brackets acting as sliding rail structures coupled to a rack. The design of FIG. 10 and the prior art design of FIG. 26 were each stimulated with a base excitation load. The base excitation load was configured as a force applied to the mounting brackets in the form of a half sine wave with an amplitude of 63G-forces (each G-force is approximately 9.8 Netwons per kilogram of mass) for two milliseconds. The simulated chassis was a stainless steel chassis, while the mounting brackets were also stainless steel. For the design of FIG. 10, the vibration absorber was manufactured from an elastomeric material.

In the plots 1101 and 1102, the transmitted force delivered to the chassis was measured at the center of the top surface of the chassis. As shown in FIG. 11, the design of FIG. 10 resulted in over a twenty-five percent reduction 1103 of the peak amplitude. The plots 1101 and 1102 demonstrate the distinct advantages of the design of FIG. 10 over the prior art design of FIG. 26. There is a visible distinction between the amplitudes of plot 1101 and plot 1102, which clearly demonstrate the improvement offered by including a vibration absorber as illustrated and described above.

Turning now to FIG. 12, illustrated therein is an alternate vibration absorber 1200 configured in accordance with one or more embodiments of the disclosure. As before, the vibration absorber 1200 includes a compressible shaft 1201 extending from a first end to a second end. The compressible shaft 1201 defines a central bore extending from the first end to the second end along a major axis 1203 of the compressible shaft 1201.

A first compressible annular flange 1204 extends distally away from the compressible shaft 1201 at the first end, while a second compressible annular flange 1205 extends distally away from the compressible shaft 1201 at the second end. Between the first compressible annular flange 1204 and the second compressible annular flange 1205, the compressible shaft 1201 defines a hub 1210.

A plurality of vibration-dampening arms 1206, 1207, 1208, 1209 extends distally from the hub 1210 and radially away from the major axis 1203. In this illustrative embodiment, rather than being arched lobes, the terminal ends 1211, 1212, 1213, 1214 of the vibration-dampening arms 1206, 1207, 1208, 1209 each define a partially rectangular cross section. The cross section is “partially rectangular” because it includes three sides, i.e., two parallel sides and a transverse terminal end, rather than four sides. Here, the fourth side is the hub 1210.

In this illustrative embodiment, rather than having eight vibration-dampening arms, the vibration absorber 1200 includes four vibration-dampening arms 1206, 1207, 1208, 1209. As before, when coupled to a mounting bracket, the interior surface of the aperture of the mounting bracket may be complementary in shape to the hub 1210 and vibration-dampening arms 1206, 1207, 1208, 1209. Accordingly, the interior surface of aperture of the mounting bracket can define one or more partially rectangular recesses into which the vibration-dampening arms 1206, 1207, 1208, 1209 situate. Advantageously, this geometry prevents the vibration absorber 1200 from rotating along its major axis 1203 when a fastener is passed through the central bore 1202 and rotated. Because there is space between the vibration-dampening arms 1206, 1207, 1208, 1209, the interior surface of the aperture of the mounting bracket can be complementary in shape to the contour of the hub 1210 along these interspaces between vibration-dampening arms 1206, 1207, 1208, 1209.

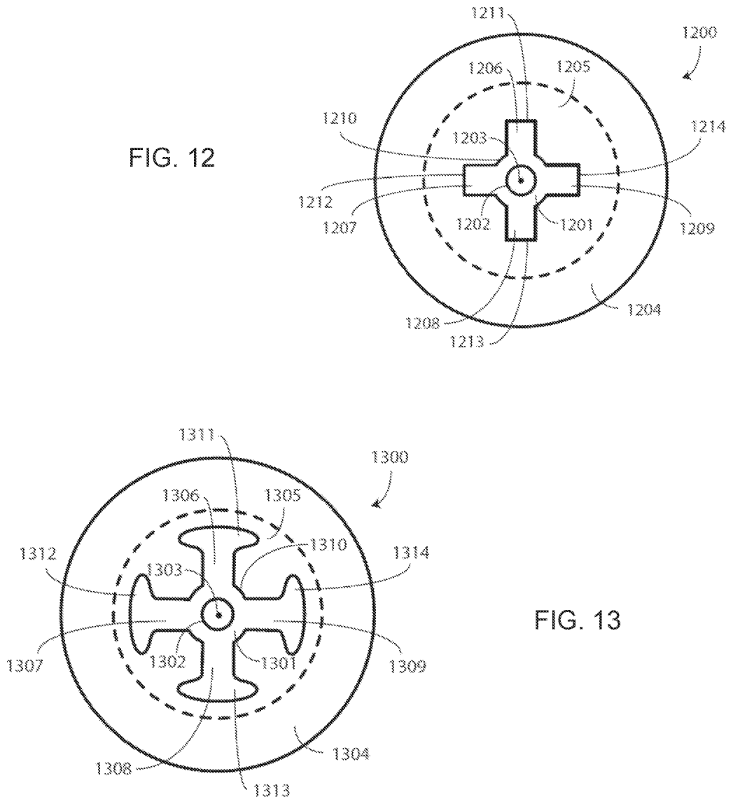

Turning now to FIG. 13, illustrated therein is an alternate vibration absorber 1300 configured in accordance with one or more embodiments of the disclosure. As before, the vibration absorber 1300 includes a compressible shaft 1301 extending from a first end to a second end. The compressible shaft 1301 defines a central bore extending from the first end to the second end along a major axis 1303 of the compressible shaft 1301.

A first compressible annular flange 1304 extends distally away from the compressible shaft 1301 at the first end, while a second compressible annular flange 1305 extends distally away from the compressible shaft 1301 at the second end. Between the first compressible annular flange 1304 and the second compressible annular flange 1305, the compressible shaft 1301 defines a hub 1310.

A plurality of vibration-dampening arms 1306, 1307, 1308, 1309 extends distally from the hub 1310 and radially away from the major axis 1303. In this illustrative embodiment, each vibration-dampening arm 1306, 1307, 1308, 1309 extends distally from the hub 1310 to a header 1311, 1312, 1313, 1314. In this embodiment, each header 1311, 1312, 1313, 1314 is wider than each vibration-dampening arm 1306, 1307, 1308, 1309. Accordingly, the vibration-dampening arms 1306, 1307, 1308, 1309 and their corresponding headers 1311, 1312, 1313, 1314 define a substantially T-shaped cross section. The cross sections are “substantially” T-shaped because the exterior surface of each header 1311, 1312, 1313, 1314 is convex. Said differently, the exterior surface, i.e., the surface of each header 1311, 1312, 1313, 1314 facing away from the hub 1310 is convex in this illustrative embodiment. Additionally, the surfaces of each header 1311, 1312, 1313, 1314 facing toward from the hub 1310 is also convex in this illustrative embodiment.

In this illustrative embodiment, rather than having eight vibration-dampening arms, the vibration absorber 1300 includes four vibration-dampening arms 1306, 1307, 1308, 1309. As before, when coupled to a mounting bracket, the interior surface of the aperture of the mounting bracket may be complementary in shape to the hub 1310 and vibration-dampening arms 1306, 1307, 1308, 1309. Accordingly, the interior surface of aperture of the mounting bracket can define one or more complementary substantially T-shaped recesses into which the vibration-dampening arms 1306, 1307, 1308, 1309 and their corresponding headers 1311, 1312, 1313, 1314 may situate. Advantageously, this geometry prevents the vibration absorber 1300 from rotating along its major axis 1203 when a fastener is passed through the central bore 1302 and rotated. Because there is space between the vibration-dampening arms 1306, 1307, 1308, 1309, the interior surface of the aperture of the mounting bracket can be complementary in shape to the contour of the hub 1310 along these interspaces between vibration-dampening arms 1306, 1307, 1308, 1309.

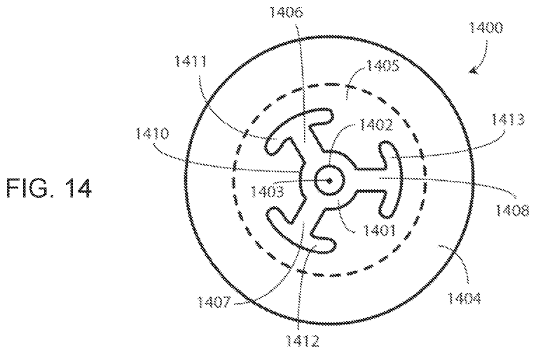

Turning now to FIG. 14, illustrated therein is an alternate vibration absorber 1400 configured in accordance with one or more embodiments of the disclosure. As before, the vibration absorber 1400 includes a compressible shaft 1401 extending from a first end to a second end. The compressible shaft 1401 defines a central bore extending from the first end to the second end along a major axis 1403 of the compressible shaft 1401.

A first compressible annular flange 1404 extends distally away from the compressible shaft 1401 at the first end, while a second compressible annular flange 1405 extends distally away from the compressible shaft 1401 at the second end. Between the first compressible annular flange 1404 and the second compressible annular flange 1405, the compressible shaft 1401 defines a hub 1410.

A plurality of vibration-dampening arms 1406, 1407, 1408 extends distally from the hub 1410 and radially away from the major axis 1403. In this illustrative embodiment, each vibration-dampening arm 1406, 1407, 1408 extends distally from the hub 1410 to a header 1411, 1412, 1413. In this embodiment, each header 1411, 1412, 1413 is wider than each vibration-dampening arm 1406, 1407, 1408.

In this illustrative embodiment, the vibration-dampening arms 1406, 1407, 1408 and their corresponding headers 1411, 1412, 1413 define an anchor-shaped cross section. This is due to the fact that the exterior surface of each header 1411, 1412, 1413 is convex, while the interior surfaces are concave. Said differently, the exterior surface, i.e., the surface of each header 1411, 1412, 1413 facing away from the hub 1410 is convex in this illustrative embodiment. By contrast, the surfaces of each header 1411, 1412, 1413 facing toward from the hub 1410 are concave in this illustrative embodiment.

In this illustrative embodiment, rather than having eight vibration-dampening arms, or four vibration-dampening arms, the vibration absorber 1400 includes only three vibration-dampening arms 1406, 1407, 1408. As before, when coupled to a mounting bracket, the interior surface of the aperture of the mounting bracket may be complementary in shape to the hub 1410 and vibration-dampening arms 1406, 1407, 1408. Accordingly, the interior surface of aperture of the mounting bracket can define one or more complementary anchor-shaped recesses into which the vibration-dampening arms 1406, 1407, 1408 and their corresponding headers 1411, 1412, 1413 may situate. Advantageously, this geometry prevents the vibration absorber 1400 from rotating along its major axis 1403 when a fastener is passed through the central bore 1402 and rotated. Because there is space between the vibration-dampening arms 1406, 1407, 1408, the interior surface of the aperture of the mounting bracket can be complementary in shape to the contour of the hub 1410 along these interspaces between vibration-dampening arms 1406, 1407, 1408.

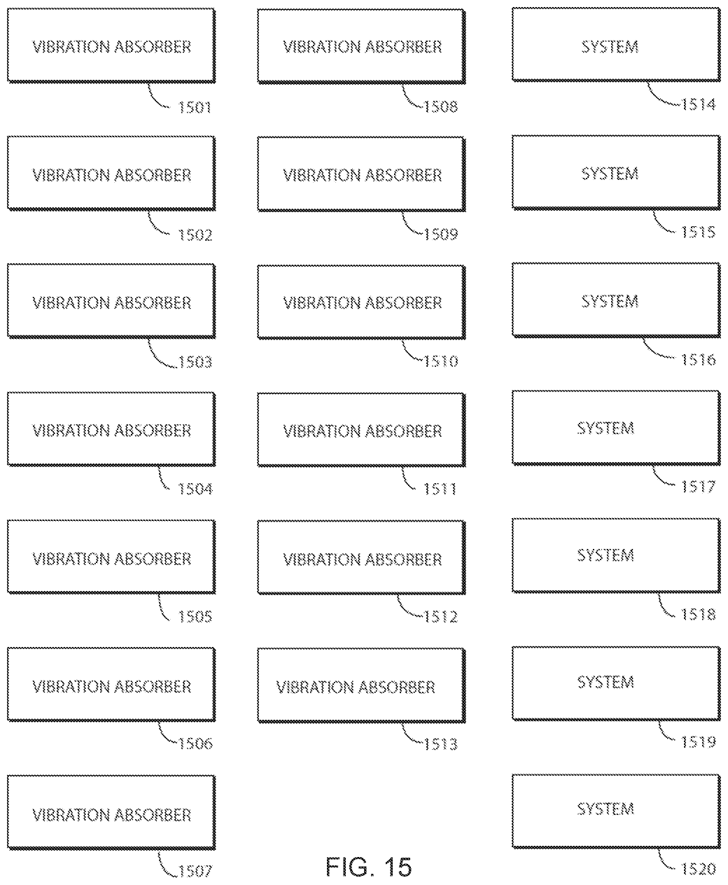

Turning now to FIG. 15, illustrated therein are various embodiments of the disclosure. At 1501, a vibration absorber comprises a compressible shaft extending from a first end to a second end. At 1501, the compressible shaft defines a cylindrical central bore extending from the first end to the second end along a major axis of the compressible shaft.

At 1501, a first compressible annular flange extends distally away from the first end. At 1501, a second compressible annular flange extends distally away from the second end. At 1501, the compressible shaft further defines a hub between the first compressible annular flange and the second compressible annular flange. At 1501, the hub comprises a plurality of vibration-dampening arms extending distally therefrom.

At 1502, each vibration-dampening arm of the plurality of vibration-dampening arms of 150 comprises an arched lobe. At 1503, the plurality of vibration-dampening arms of 1502 comprises eight arched lobes.

At 1504, each arched lobe of 1502 comprises an exterior surface defined by a contour that is at least partially parabolic. At 1503, the first compressible annular flange of 1502 has a greater diameter than the second compressible annular flange. At 1506, the second compressible annular flange of 1505 extends distally farther from the shaft than the arched lobe.

At 1507, the vibration absorber of 1506 is manufactured from an elastomeric material. At 1508, the compressible shaft, the first compressible annular flange, the second compressible annular flange, and the plurality of vibration-dampening arms of 1506 are manufactured as a unitary component.

At 1509, a terminal end of each vibration-dampening arm of 1501 defines a partially rectangular cross section. At 1510, each vibration-dampening arm of 1501 extends distally from the hub to a header having that is wider than the arm. At 1511, each header of 1510 comprises a convex exterior surface.

At 1512, a first surface of the header of 1510 facing away from the hub and a second surface of the header facing toward the hub are convex. At 1513, a first surface of the header of 1510 facing away from the hub is convex and a second surface of the header facing toward the hub is concave.

At 1514, a vibration absorber system comprises a mounting bracket defining at least one aperture having an interior surface. At 1514, the vibration absorber system comprises at least one vibration absorber coupled to the mounting bracket through the at least one aperture.

At 1514, the at least one vibration absorber comprises a first annular flange situated against a first major face of the mounting bracket. At 1514, the at least one vibration absorber comprises a second annular flange situated against a second major face of the mounting bracket.

At 1514, the at least one vibration absorber comprises a shaft coupling the first annular flange to the second annular flange. At 1514, the shaft defines a hub situated within the at least one aperture. At 1514, the hub comprises a plurality of vibration-dampening arms situated between the hub and the interior surface.

At 1515, the shaft of 1514 defines a cylindrical central bore. At 1515, the vibration absorber system of 1514 further comprises a fastener situated within the cylindrical bore.

At 1516, the interior surface of the aperture of 1515 defines a plurality of contours complementary in shape to the plurality of vibration-dampening arms. At 1517, each vibration-dampening arm of 1516 extends to a header biased against the interior surface.

At 1518, a vibration absorber system comprises a chassis and a mounting bracket coupled to a side of the chassis by at least one fastener. At 1518, the vibration absorber system comprises at least one vibration absorber. At 1518, the vibration absorber comprises a hub comprising a plurality of vibration-dampening arms compressed between the at least one fastener and the mounting bracket. At 1518, the hub comprises a first annular flange compressed between the chassis and the mounting bracket.

At 1519, the fastener of 1518 comprises a head and a shaft. At 1519, the at least one vibration absorber 1519 comprises a second annular flange compressed between the head and the mounting bracket. At 1520, the fastener of 1519 comprises a screw. At 1520, the vibration absorber system of 1519 further comprises a nut situated inside the chassis and coupled to the screw.

Embodiments of the disclosure provide numerous advantages over prior art systems and constructs. The vibration absorbers described above comprise a hub with a plurality of vibration-dampening arms that extend distally outward from the hub. This provides more contact surface area. Moreover, the inclusion of the vibration-dampening arms precludes rotation of the hub within an aperture of a mounting bracket when a fastener is positioned within the central bore of the vibration absorber and rotated. The interior surface of the aperture of the mounting bracket is complementary in shape to the hub and/or vibration-dampening arms. When over-molded, the vibration absorber becomes embedded in the mounting bracket. Additionally, embodiments of the present disclosure employ a mounting bracket with a vibration absorber manufactured from an elastomeric material to reduce vibration transmissibility in relatively small and stationary structures. Moreover, embodiments of the disclosure rely on the material properties of the vibration absorber to damp vibration. Vibration absorbers described above do not employ the interaction of several masses in order to absorb vibration levels.

Other distinctions between these—and other references—will be obvious to those of ordinary skill in the art having the benefit of this disclosure. For example, there is uniqueness in over-molding the vibration absorber to the mounting bracket because it reduces part count over other solutions. Many electronic equipment racks are designed to dampen vibrations, while others are not. Use of an over-molded vibration absorber in accordance with the teachings above allow adaptation of any electronic equipment into racks and/or cabinets that do not provide vibration damping. Moreover, vibration absorbers configured in accordance with embodiments of the disclosure are easy to fabricate. While there are other solutions to dampen rack mount equipment from vibrating, embodiments of the disclosure lend themselves to simplicity. Embodiments of the disclosure provide a simple design and offer a lower-cost solution compared to alternative designs and methods. The over-mold implementation reduces assembly time and minimizes part losses during handling and installation. Embodiments of the disclosure sustain longevity of electronic equipment in the field that would otherwise be subjected to daily office vibrations.

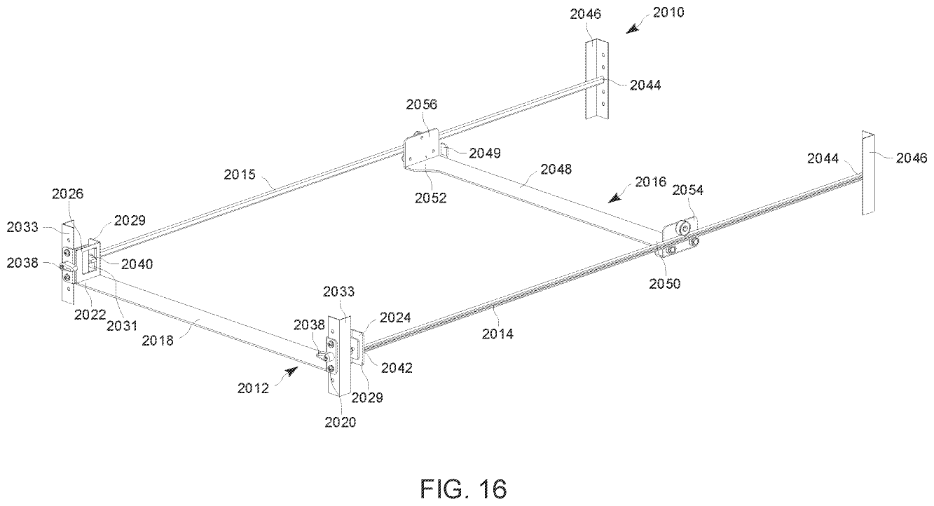

Referring to FIG. 16, an illustrative example of a mounting bracket or bracket assembly 2010 for supporting and attaching a component, such as an electronic component, to a rack is shown. The bracket assembly includes a front bracket 2012, elongate side supports 2014 and 2015, and a rear bracket 2016. Rear bracket 2016 can be moved toward or away from front bracket 2012 to accommodate electronic components of different depths.

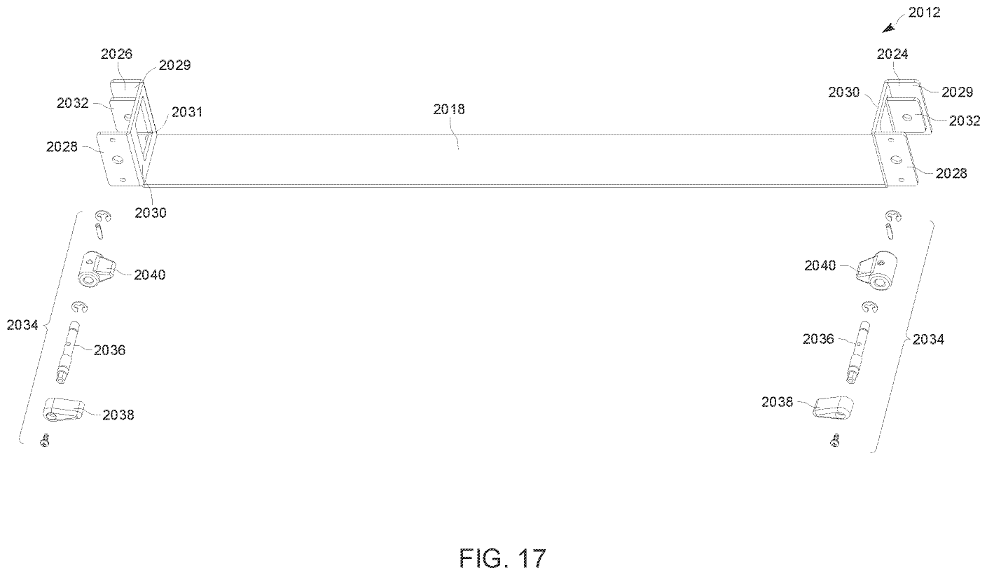

Front bracket 2012 includes an elongate front support 2018 that supports a front portion of a component. The front bracket includes opposed longitudinal ends 2020 and 2022. Flanges 2024 and 2026 are attached to, or with, longitudinal ends 2020 and 2022, respectively, such that flanges extend perpendicularly from the front support. In the example shown in FIG. 16 and as best seen in FIG. 17, each of flanges 2024 and 2026 have a rectangular C-shape having parallel end walls 2028 and 2029 and a middle wall 2030 perpendicular to and connecting the end walls. The middle wall includes an opening 2031. An intermediate wall 2032 is attached to, or formed with, middle wall 2030 such that the intermediate wall extends perpendicular of the middle wall and is disposed between and parallel to the end walls. Front mounting brackets 2033 are attached to end walls 2028 for attaching the bracket assembly and electronic component supported on the bracket assembly to the rack.

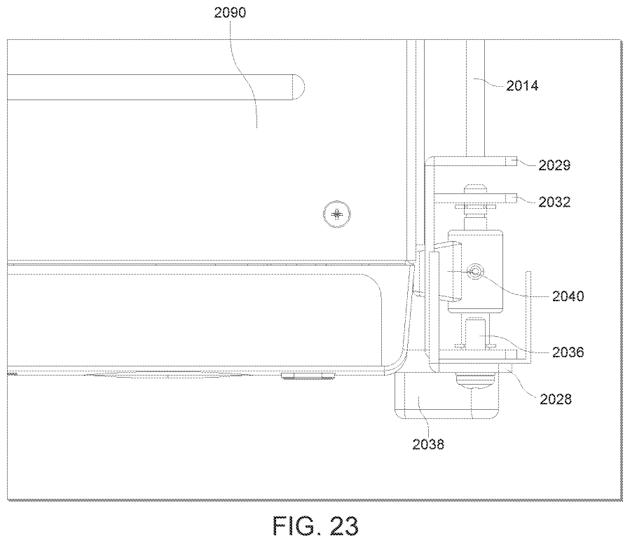

Referring to FIG. 17, attached to each of flanges 2024 and 2026 is a latching mechanism 2034 that prevents displacement of an electronic component supported by the bracket assembly in a direction from the rear bracket toward the front bracket and/or from one side support to another side support. The latching mechanism includes a rod 2036 and first and second tabs 2038 and 2040 attached to the rod. The first and second tabs are spaced from each other. Rod 2036 is pivotably received in holes of each of flanges 2024 and 2026 such that second tab 2040 is disposed between parallel end walls 2028 and 2029 and first tab 2038 is adjacent to and in front of end wall 2028 and spaced from middle wall 2030 and end wall 2029 (as best seen in FIG. 23).

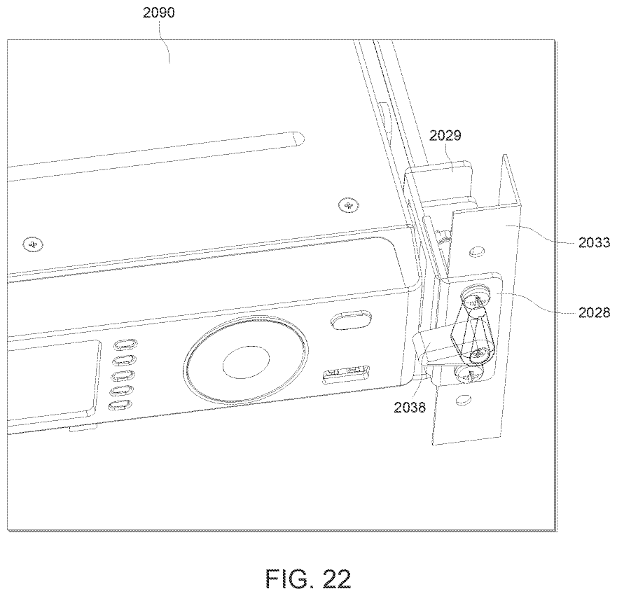

Rod 2036, first cam or tab 2038, and second cam or tab 2040 pivots between a lock position (shown in FIG. 16) in which first tab 2038 contacts a front portion of a component supported by the bracket assembly and second tab 2040 contacts a side portion of the electronic component supported by the bracket assembly, and a release position (as best seen in dashed lines in FIG. 22) in which the first tab is spaced from the front portion and the second tab is spaced from the side portion relative to the lock position. Second tab 2040 extends through opening 2031 in the lock position and does not extend through the opening in the release position.

Referring back to FIG. 16, elongate side supports 2014 and 2015 include longitudinal opposed ends 2042 and 2044. Ends 2042 are fixedly attached to the longitudinal opposed ends of the front bracket. In the example shown in FIG. 1, the elongate side supports are attached to end wall 2029 of flanges 2024 and 2026. Rear mounting brackets 2046 are attached to ends 2044 of the elongate side supports for attaching the bracket assembly and the electronic component supported by the bracket assembly to the rack.

Rear bracket 2016 includes an elongate rear support 2048 that supports a rear portion of an electronic component. The rear support includes opposed longitudinal ends 2050 and 2052. Additionally, rear support 2048 is configured to prevent displacement of a component supported by the bracket assembly in a direction from the front bracket (or front support) toward the rear support. At least one tab 2049 is attached or formed with the rear support. In the example shown in FIG. 16, tab 2049 is fixedly attached perpendicularly to, or perpendicularly formed with, the rear support to prevent the above displacement. However, other examples of the bracket assembly may include a rear support having a lip and/or other structures to prevent displacement of an electronic component supported by the bracket assembly toward the rear support. Rear bracket 16 additionally includes planar flanges 2054 and 2056 that are fixedly attached to, or formed with, opposed ends 2050 and 2052 of rear support 2048.

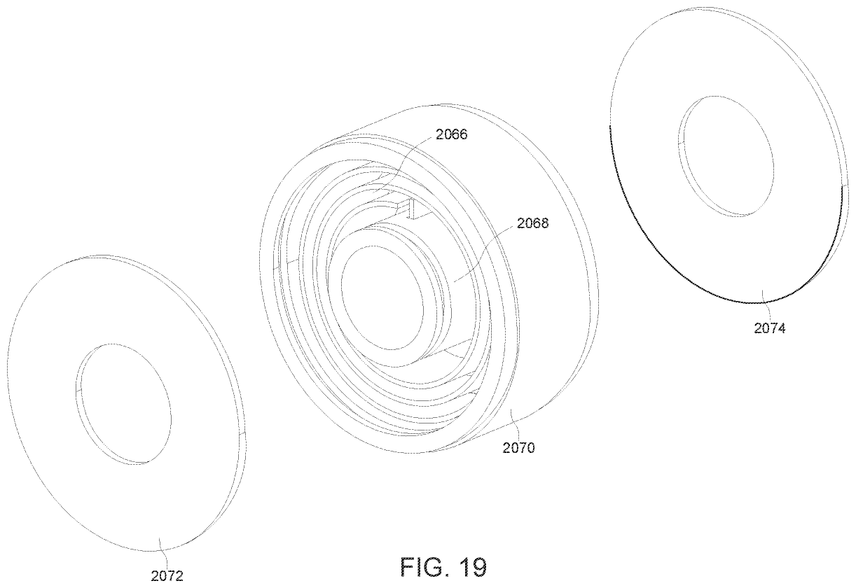

Referring to FIGS. 18-19, a roller assembly is associated with each planar flange 2054 and 5206 and define a channel to slidably engage a respective side support. In the example shown in FIGS. 18-19, the roller assembly includes at least one upper roller 2058 and at least one lower roller 2060 that are rotatably attached to each planar flange 2054 and 2056. The upper and lower rollers are positioned on the planar flange to define a channel 2062 therebetween to slidably engage or receive one of elongate side supports 2014 and 2015 such that the upper and lower rollers contact the received side support. Although the example shown in FIGS. 18-19 include a single upper roller and two lower rollers, other examples of the bracket assembly of the present disclosure may include two or more upper rollers and/or one, three or more lower rollers

A biasing mechanism 2064 is attached to each planar flange to urge the rear bracket toward the front bracket. In the example shown in FIG. 19, biasing mechanism 2064 includes a spring 2066 contained within upper roller 2058. One end of spring 2066 is attached to a post 2068 that rotatably attaches upper roller 2058 to the planar flange and the other end of the spring is attached to an inner surface of a body 2070 of the upper roller. Body 2070 or an outer surface of body 2070 is made of one or more suitable materials that promote friction between the rollers and the side supports. For example, body 2070 may be made of rubber materials (such as ethylene propylene diene monomer rubber or neoprene). Additionally, outer surface of body 2070 may include texture, such as a plurality of bumps, projections, threads, cavities, and/or any suitable combination to promote friction between the rollers and the side supports. Front and rear covers 2072 and 2074 contain or at least substantially contain spring 2066 within the upper roller. The springs are adapted to urge the upper rollers to rotate in a direction to urge the rear bracket toward the front bracket. For example, biasing mechanism 2064 attached to planar flange 2054 urges the upper roller attached to that flange to rotate in a counter-clockwise direction, while the biasing mechanism attached to planar flange 2056 urges the upper roller attached to that flange to rotate in a clockwise direction. Both biasing mechanisms 2064 collectively urge the rear bracket to move toward the front bracket.

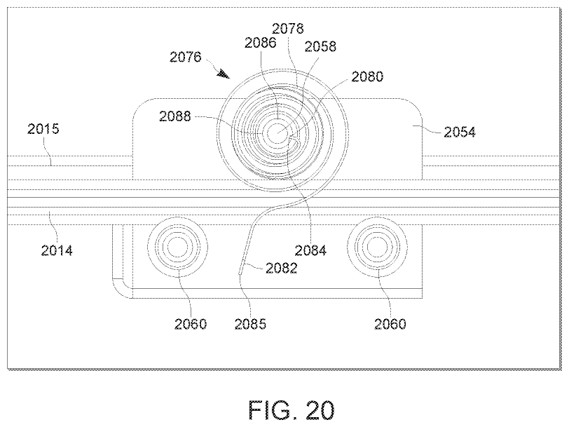

Referring to FIG. 20, another example of biasing mechanism 2064 is shown, which is primarily (or at least substantially) external the upper roller and is indicated at 2076. Biasing mechanism 2076 includes a spring 2078 having opposed ends 2080 and 2082. End 2080 is attached to upper roller 2058 (such as received in a hole 2084 of a front cover 2086 that rotates only with body 2088 of the upper roller), while end 2082 is attached to the planar flange (such as received in a hole 2085 of the planar flange). Although the examples of FIGS. 18-20 show that the biasing mechanisms are adapted to urge the upper rollers, the biasing mechanisms may alternatively, or additionally, urge the lower rollers such that the rear bracket is urged toward the front bracket.

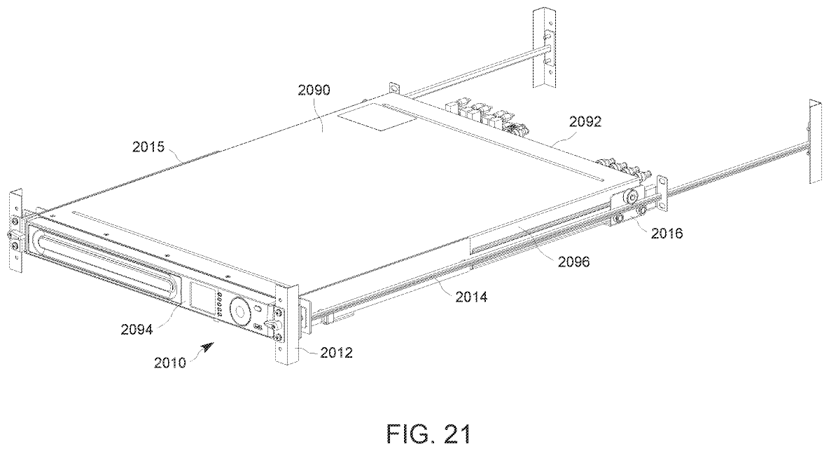

Referring to FIGS. 21-23, bracket assembly 2010 is shown supporting a component 2090. Front portion of the electronic component is on the front support of front bracket 2012, while the rear portion of the electronic component is on the rear support of rear bracket 2016. Because rear bracket 2016 is slidably connected to front bracket 2012 and side supports 2014 and 2015 and is urged by the biasing mechanism toward the front bracket, a person can push the rear bracket away from the front bracket to accommodate components of various depths without the use of any tools. The tab on the rear support contacts a rear portion 2092 of electronic component 2090 and prevents the supported electronic component from displacing toward the rear bracket (or moving in a direction from the front bracket to the rear bracket).

A user can move first tabs 2038 of latching mechanism 2034 to a lock position in which first tabs 2038 contact front portions 2094 of electronic component 2090 and in which second tabs 2040 contact side portions 2096, which prevents the supported electronic component from displacing toward the front bracket (or moving in a direction from the rear bracket to the front bracket) and/or displacing sideways. When the first and second tabs are in the lock position, electronic component 2090 is supported on the supports of the front and rear brackets and is contained by the tab on the rear support and the first and second tabs. Particularly when the first and second tabs are not made of metal, metal-on-metal contact is avoided and vibrations are minimized. A user can move the first tabs to the release position (shown in dashed lines in FIG. 22) when component 2090 is to be removed from the bracket assembly.

In contrast, prior art bracket assemblies or mounting brackets support components of only a specific depth, which requires an inventory of bracket assemblies of various depths. Alternatively, prior art bracket assemblies require one or more tools to adjust to a particular depth of the electronic component prior to attaching the electronic component and bracket assembly to a rack. The above prior art systems generally take more effort and time for installing electronic components in a rack.

It will be appreciated that the invention is not restricted to the particular embodiment that has been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word “comprise” or a derivative thereof, when used in a claim, is used in a nonexclusive sense that is not intended to exclude the presence of other elements or steps in a claimed structure or method.

Accordingly, the specification and figures are to be regarded in an illustrative rather than a restrictive sense, and all such modifications are intended to be included within the scope of present disclosure. The benefits, advantages, solutions to problems, and any element(s) that may cause any benefit, advantage, or solution to occur or become more pronounced are not to be construed as a critical, required, or essential features or elements of any or all the claims.

What is claimed is:

1. A vibration absorber, comprising:
a compressible shaft extending from a first end to a second end and defining a cylindrical central bore extending from the first end to the second end along a major axis of the compressible shaft;
a first compressible annular flange extending distally away from the first end; and
a second compressible annular flange extending distally away from the second end;
the compressible shaft further defining a hub between the first compressible annular flange and the second compressible annular flange, the hub comprising a plurality of vibration-dampening arms extending distally therefrom.

2. The vibration absorber of claim 1, wherein each vibration-dampening arm of the plurality of vibration-dampening arms comprising an arched lobe.

3. The vibration absorber of claim 2, each arched lobe comprising an exterior surface defined by a contour that is at least partially parabolic.

4. The vibration absorber of claim 1, wherein a terminal end of each vibration-dampening arm defines a partially rectangular cross section.

5. The vibration absorber of claim 1, each vibration-dampening arm extending distally from the hub to a header having that is wider than the each vibration-dampening arm.

6. The vibration absorber of claim 5, wherein each header comprises a convex exterior surface.

7. The vibration absorber of claim 5, wherein a first surface of the header facing away from the hub is convex and a second surface of the header facing toward the hub is concave.

8. A vibration absorber system, comprising:
a mounting bracket defining at least one aperture having an interior surface; and
at least one vibration absorber coupled to the mounting bracket through the at least one aperture, the at least one vibration absorber comprising:
a first annular flange situated against a first major face of the mounting bracket;
a second annular flange situated against a second major face of the mounting bracket; and
a shaft coupling the first annular flange to the second annular flange, the shaft defining a hub situated within the at least one aperture, the hub comprising a plurality of vibration-dampening arms situated between the hub and the interior surface.

9. The vibration absorber system of claim 8, the shaft defining a cylindrical central bore, further comprising a fastener situated within the cylindrical bore.

10. The vibration absorber system of claim 9, wherein the interior surface of the aperture defines a plurality of contours complementary in shape to the plurality of vibration-dampening arms.

11. The vibration absorber system of claim 10, wherein each vibration-dampening arm extends to a header biased against the interior surface.

12. An adjustable bracket assembly, comprising:
an elongate front support having opposed longitudinal ends;
first and second elongate side supports each attached to a respective opposed longitudinal end of the front support;
an elongate rear support having opposed longitudinal ends with each end having a planar flange; and
a roller assembly associated with each planar flange and defining a channel to slidably engage a respective elongate side support.

13. The assembly of claim 12, further comprising a biasing mechanism attached to each planar flange that urges the rear support and planar flanges toward the front support.

14. The assembly of claim 13, wherein the biasing mechanism includes a spring positioned to urge the at least one roller of the roller assembly to rotate in a direction such that the rear support and planar flanges are urged toward the front support.

15. The assembly of claim 14, wherein the spring is at least substantially contained within the at least one roller.

16. The assembly of claim 14, wherein at least a substantial portion of the spring is external the at least one roller.

17. The assembly of claim 12, further comprising a latch mechanism that is attached to the front support and that contacts a front portion of an electronic component supported by the bracket assembly to prevent displacement of the electronic component in a direction from the rear support toward the front support.

18. The assembly of claim 17, wherein the latch mechanism includes a rod and a first tab attached to the rod, wherein the first tab pivots between a lock position in which the first tab contacts the front portion of the electronic component, and a release position in which the first tab is spaced from the front portion of the electronic component relative to the lock position.

19. The assembly of claim 18, wherein the latch mechanism further includes a second tab attached to the rod and spaced from the first tab, wherein the second tab contacts a side portion of the electronic component when the first tab is in the lock position, and the second tab is spaced from the side portion of the electronic component relative to the lock position when the first tab is in the release position.

20. The assembly of claim 12, wherein the roller assembly includes:
at least one upper roller rotatably attached to each planar flange; and
at least one lower roller rotatably attached to each planar flange, wherein, for each of the planar flanges, the at least one upper roller and the at least one lower roller define a channel therebetween to slidably receive the corresponding side support, the upper and lower rollers being positioned to contact the corresponding side support when received in the channel.
